(19) United States
(12) Patent Application Publication
(10) Pub. No.: US 2025/0327169 A1
(43) Pub. Date: Oct. 23, 2025

(54) HYBRID COATING PROCESS BY PVD AND THERMAL DIFFUSION

(71) Applicant: HUSQVARNA AB, Huskvarna (SE)

(72) Inventors: Niklas SARIUS, Jonkoping (SE); Helena SKOGLUND, Vadstena (SE); Muhammad JUNAID, Linkoping (SE); Santiago PINATE, Boras (SE)

(21) Appl. No.: 18/870,853

(22) PCT Filed: May 29, 2023
(86) PCT No.: PCT/SE2023/050522

§ 371 Date: Dec. 2, 2024

(30) Foreign Application Priority Data
Jun. 2, 2022 (SE) 2250668-7

(51) Int. Cl. C23C 14/24; B27B 33/14; C23C 14/58; C23C 28/04; C25D 5/50

(52) U.S. Cl. CPC C23C 14/24; C23C 14/5806; C23C 28/046; C25D 5/50; B27B 33/142

(57) ABSTRACT

There is disclosed method for manufacturing a cutting device comprising the steps of a) providing a base comprising a cutting edge, wherein the base is made of a base material comprising a first element, b) applying a first coating layer comprising a second element on the top surface of the base by a method selected from PVD and electroplating, c) heat treating the base, wherein the step c) is performed at a temperature and for a time period sufficient for the second element to diffuse partly into the base and for the first element to diffuse at least partly into the first coating layer, whereby a gradient of a compound is formed by a reaction of the first element and the second element. Advantages include that wear resistance properties and stay sharp properties are improved, which are particularly suitable for surfaces of cutting devices. Furthermore, the method is environmentally friendly.

### TECHNICAL FIELD

This disclosure relates to a method for coating a substrate involving physical vapor deposition (PVD) or electroplating followed by a thermal diffusion (TD) process.

### BACKGROUND

Hard chrome plating, in various forms, has been one of the standards to improve resistance towards wear and corrosion for stainless steel components. Use of hard chrome coating by the electroplating process is banned by European union as of September 2017. Several studies have shown that chromium is a toxic element that negatively affects plant metabolic activities, hampering crop growth and yield and reducing vegetable and grain quality. The oxidation state and solubility affects the toxicity of chromium compounds. Cr(6+) compounds, which are powerful oxidizing agents and thus tend to be irritating and corrosive, appear to be especially toxic. There is a need for a replacement of coatings comprising this element, which still provide desired coating quality.

WO 2020/188145 A1 discloses a method for producing an object comprising a chromium-based coating on a substrate, wherein a first layer is deposited on a substrate through at least two electroplating cycles from a trivalent chromium bath and at least one heat treatment is performed to form a second layer. The first layer is predominantly formed of chromium and chromium carbide. The material of the second layer is selected from a group consisting of: chromium oxide, carbon, and a combination of chromium oxide and carbon.

KR10-0445752 B1 discloses a method of coating chromium carbide on a metal material surface. The method includes performing chromium plating on the surface of the metal material, and then a diffusing heat treatment of the chromium plated metal material.

WO 2016/139616 A1 discloses a method of modifying a cutter link of cutting chain for a chainsaw, the method including diffusing a diffusion agent into material at a treated surface. The diffusion agent may be chromium.

WO 2019076458 A1 discloses a cutting chain for a chainsaw. A coating may be formed by diffusing an element, such as chromium, into the surface.

There is a need to provide a method for coating, which enhances the wear resistance properties, stay sharp properties and hardness of surfaces such as surfaces of cutting devices, and which is environmentally friendly and efficient and controllable regarding providing desired properties of such a coating.

### BRIEF SUMMARY OF THE INVENTION

It is an object of the invention to obviate at least some of the problems in the prior art.

In a first aspect, there is provided a method for manufacturing a cutting device (200) comprising the steps of:
a) providing a base (210) comprising a cutting edge (220), wherein the base (210) is made of a base material (300) comprising a first element (301),
b) applying a first coating layer (240) comprising a second element (302) on the top surface (230) of the base (210) by a method selected from PVD and electroplating,
c) heat treating the base (210), wherein the step c) of heat treating is performed at a temperature and for a time period sufficient for the second element (302) to diffuse partly into the base (210) and for the first element (301) to diffuse at least partly into the first coating layer (240), whereby a gradient of a compound (310) is formed by a reaction of the first element (301) and the second element (302).

In a second aspect of the invention, a cutting device is provided, which is manufactured according to any of the embodiments of the described method.

### BRIEF DESCRIPTION OF THE DRAWINGS

The invention will be described in further detail under reference to the accompanying drawings in which:

FIG. 1 shows a base (210) of a cutting device, made of a base material (300), with a cutting edge (220), having a coating layer (240) in contact with the cutting edge, said coating comprising a gradient of a compound (310);

FIG. 2 shows three different states of a base material (300) coated with a coating layer (240) according to the present invention:
x.: a first coating layer (240) comprising a second element (302) is applied using PVD or electroplating on the top surface (230) of a base material (300) comprising a first element (301).
y.: a base (210) coated as in x. where the second element (302) has diffused partly into the base material (300) and where the first element (301) has diffused partly into the coating layer (240) and has created a gradient of a compound (310) created by the elements (301, 302) between the base material (300) and the coating material of the coating layer (240), the gradient of the compound (310) not reaching the outermost surface of the coating layer (240) (i.e. the upper surface in the FIGS. 2. x, y, z);
z.: a base (210) coated as in x. where the second element (302) has diffused partly into the base material (300) and where the first element (301) has diffused fully into the coating layer (240) and has created a gradient of a compound (310) created by the elements (301, 302) reaching from the base material (300) and through the coating material of the coating layer (240), the gradient of the compound (310) reaching the outermost surface of the coating layer (240).

FIG. 3 shows a steel base coated with pure Chromium (left) and gradients created after thermal diffusion (right). In this embodiment, elements (301) of the base material has diffused partly into the coated layer and elements (302) of the coating layer has diffused partly into the base material, creating a gradient of compounds (310) between the materials, resulting in the following order of materials: Steel (base), Crₓ·Fe_{y}·C_{z}, CrC, pure Cr coating.

FIG. 4 shows a steel base coated with pure Aluminum (left) and gradients created after thermal diffusion (right). In this embodiment, elements (Fe) of the base material (steel) has diffused fully into the coated layer. A gradient of FeAl is created by the elements, with an outermost layer of FeₓAl_{y} and an intermediate layer of Fe_{z}Al_{w}.

FIG. 5 shows a cutterlink of a chainsaw.

### DETAILED DESCRIPTION

The present invention relates to a method for coating a substrate/a surface of a base. More particularly, it relates to a method for coating a metal, e.g. chromium, on a surface of a base being a cutting device comprising carbon in the base material. The method also applies to other base and coating materials, as is further exemplified in the 10 embodiments and claims. The method results in a coating with excellent wear resistance and stay sharp properties by increasing the possibility to control the coating thickness and compound gradients created, as compared with the conventional methods. The process is also efficient and environmentally friendly in relation to many existing methods.

Physical vapour deposition (PVD) coatings are suitable for increasing wear resistance of a cutting edge, such as the cutting edge of cutter links in a saw chain. Main advantages of using PVD are that it is a environmental friendly, low temperature, and scalable process. To achieve a good adhesion to the surface of a base to be coated and functional properties of such a coating, a high temperature process or in-situ high energetic plasma etching process or the combination of both is presently needed prior to the coating deposition. These process parameters can affect the hardness of the bulk material (e.g. by annealing) and make it softer, which is not desirable. To achieve the right bulk hardness a post coating heat treatment is then required, which can affect the material and functional properties of the coating and can also lead to delamination due to the difference in thermal expansion between the bulk and the coating. This also leads to longer production times.

An alternative method for coating is the electroplating process. These however have the downside of a lower control of the thickness distribution compared to PVD, and in order to guarantee a good adhesion with this process, a pre-treatment or an interlayer can be required, which leads to longer production times.

With the coating method of the disclosed invention, the coating could instead be deposited on unhardened cutterlinks before the hardening step. As it is today, cutterlinks are heat treated (hardened) first and then electroplated (using Cr(6+)). With this new hybrid coating process combining PVD or electroplating with thermal diffusion, the coating material (metal) is applied first and the following treatment works as hardening and as a diffusion process to produce a layer of a compound, such as CrC. It is also possible to apply the hybrid process to an already hardened cutter link (i.e. after heat treatment).

Coatings produced by a thermal diffusion (TD) process have an excellent adherence due to the diffusion zone, which in essence, acts as a transition zone between the bases surface and the coating, promoting adhesion between materials. Adhesion of coating and coating wear properties are very important for the success of the coating as a replacement of hard chrome. The main challenge of diffusion processes is the robustness of the production method, as there is a difficulty to predict and control a precise coating thickness, and also to coat only specific areas.

The precise tolerances as well as coating on specific areas by masking can be achieved by PVD or by electroplating. Masking of cutterlinks to have coating only on specific areas is a challenge, which is easily achievable in PVD processes. A coating method combining PVD or electroplating with a thermal diffusion process can thereby provide the desired results in terms of better adhesion, coating on a specific area and good functional properties. It is referred to as a hybrid process due to the use of a traditional coating method, e.g. PVD or electroplating, to provide a source material as a coating that covers efficiently complex geometries, in combination with TD. The initial coating produced by PVD or electroplating provides a homogenous layer covering the targeted surface. The thermal diffusion process is then used to diffuse the coating material inwards while also “consuming” the different elements present in the base material, diffusing them outwards, thereby provoking the formation of a compound formed by a reaction of an element in the base material and an element in the coating applied on the surface of the base, and enhances the adherence to the base material. The combination of the methods provides full control of the final coated areas and thickness.

By using PVD as the initial coating method it is possible to very precise control the thickness of the final layers. The initial coating produced by PVD or electroplating provides a homogenous material covering the targeted surface. The parameters (temperature, duration) of the thermal diffusion can be varied to achieve a precise thickness of the coating, diffusion layers, gradient of created compounds and thereby properties of the coating. The thermal diffusion process provokes the formation of a gradient compound, e.g. chromium carbide, and enhances the adherence to the base material.

As the process temperature and time is adapted to control the diffusion and transformation process, a type of multi-layered structure with diffusion zones can be produced, with gradients from the base to the coating layer. For instance, steel rich in carbon will provide the carbon content necessary to produce a carbide coating. For example, coating pure Chromium on such a base results in Chromium Carbide. The final coating can result in a sort of multilayer if the processing time is shortened due to the partial transformation, allowing full control of the final thickness of the compound (e.g. carbide) layer. The final thickness is also based on the initial thickness of the coating material. The interphase between coating and base is no longer only steel but a gradient of a mixture between the elements such as iron, chromium, and carbon in the base and the coating, further promoting a gradient in hardness.

For example, a pure Chromium coating can be deposited by PVD or electroplating onto the surface of a cutterlink only on specific areas by using a special cutter link holder. The process parameters are adjusted to achieve a coating thickness of e.g. between 1-5 μm. PVD or electroplating coating is applied on the cutterlinks after the stamping (hardening) process. The pure Chromium acts as a source of metal during the thermal diffusion process, carried out in a heat treatment furnace. The coated samples are placed in the furnace with a temperature ranging between 600° C. and 1200° C., such as around 800-1100° C., for a duration of 40-360 minutes, such as around 50-70 minutes, varying the parameters on demand to adjust the final thickness of the deposited coating. The Chromium will diffuse into the base material (here an iron based alloy comprising carbon) during the thermal diffusion process and will chemically react with carbon to form chromium carbide (CrC). After completion, the pure chromium has been transformed to a CrC layer, or to a combination of a chromium layer with a CrC layer between the chromium clayer and the base material.

If the an Cr layer is to be electroplated, Cr(3+) should be used, as using Cr(6+) as the metal ion to form the Cr layer is undesirable. When electroplated, the Cr is in metal ion form in a solution, and the Cr(6+) is toxic. However, for PVD Cr can be applied without any hazard since it is not in the metal ion form.

As Fe from the base diffuses into the applied coating, a compound of Crₓ:Fe_{y}:C_{z} can also be formed. There may in the final product after partial diffusion for example be an outermost layer of pure Chromium, followed by a CrC layer, a Crₓ:Fe_{y}:C_{z} layer, and a base material such as steel (FIG. 3).

While the coating material in the coating can be pure Chromium, other elements such as Carbon, Iron, Titanium, Boron, Aluminum, Nickel, Vanadium, Niobium or Silicon or a combination thereof can be used and combined with suitable base materials to achieve desired compounds in the coating.

Tailored coatings and properties are possible if additional single metal layers, or metal multilayers, are coated as coating source materials. For instance, an upper layer of pure Al and an interlayer of Si can be applied, capable of producing AlₓSi_{y} and FeₓAl_{Y} metallic compounds as a coating. Cr and B can be applied to form other types of metallic phases. The same concept can be applied to Ti, encouraging a very hard upper layer based on TiC, whereas a softer (than TiC) material made out of Crₓ:Fe_{y}:C_{z} is found underneath, diffused toward the base material.

In the first aspect of the invention, there is provided a method for manufacturing a cutting device (200) comprising the steps of:
a) providing a base (210) comprising a cutting edge (220), wherein the base (210) is made of a base material (300) comprising a first element (301),
b) applying a first coating layer (240) comprising a second element (302) on the top surface (230) of the base (210) by a method selected from PVD and electroplating,
c) heat treating the base (210),
wherein the step c) of heat treating is performed at a temperature and for a time period sufficient for the second element (302) to diffuse partly into the base (210) and for the first element (301) to diffuse at least partly into the first coating layer (240),
whereby a gradient of a compound (310) is formed by a reaction of the first element (301) and the second element (302).

In one embodiment of the method, the heat treatment in step c) is carried out so that the diffusion of the first element (301) occurs only partially into the first coating layer (240) (FIG. 2. y.).

In one embodiment of the method, the heat treatment in step c) is carried out so that the diffusion of the first element (301) occurs only into at most 5, 10, 20, 30, 40, 50, 60, 70, 80, 90 or 99% of the thickness of first coating layer (240), in the direction from the base outwards through the first coating layer (240), in at least 90% of the area of the first coating layer (240). The wording that the diffusion occurs at most 5, 10, 20, 30, 40, 50, 60, 70, 80, 90 or 99% of the thickness means that in one embodiment the diffusion occurs into at most 5% of the thickness, in another embodiment the diffusion occurs into at most 10% of the thickness, in another embodiment the diffusion occurs into at most 20% of the thickness, in another embodiment the diffusion occurs into at most 30% of the thickness, in another embodiment the diffusion occurs into at most 40% of the thickness, in another embodiment the diffusion occurs into at most 50% of the thickness, in another embodiment the diffusion occurs into at most 60% of the thickness, in another embodiment the diffusion occurs into at most 70% of the thickness, in another embodiment the diffusion occurs into at most 80% of the thickness, in another embodiment the diffusion occurs into at most 90% of the thickness, in another embodiment the diffusion occurs into at most 99% of the thickness.

In another embodiment of the method, the heat treatment in step c) is carried out so that the diffusion of the first element (331) in the base material occurs fully into the first coating layer (240) (FIG. 2. z.).

During thermal diffusion, the second element (302) of the first coating layer (240) diffuses into the base material (300) and the first element (301) of the base material diffuses into the first coating layer (240). As the thickness of the coating after diffusion may vary slightly over the whole area of the layer (240), and diffusion might not be completely even, an exact percentage of diffusion which applies to the whole area of the coated layer (240) can not always be given. There may be locations where a few elements (301) has reached beyond the intended percentage and formed compound (310) is present. For all embodiments considered to have only partial diffusion, there is an area of at least 90% the outermost layer present after diffusion which still comprises pure coating material comprising the second element (302) and no normed compound (310) (FIG. 2. y.). Full diffusion means that the first element (301) has diffused all the way through at least 90% of the area of the applied first coating layer (240) and the formed compound (310) is present in the outermost layer of the first coating layer (240) (FIG. 2. z.). There may however still be a gradient of the compound (310) formed within the diffusion zone, such that the proportion of the compound (310) decreases in the direction from the base towards the outermost surface of the first coating layer (240).

In one embodiment of the method, in step b) at least one additional coating layer (241) comprising a third element (303) is applied onto the first coating layer (240) by a method selected from PVD and electroplating before step c) of heat treating, such that during the step c) of heat treating the third element (303) comprised in the at least one additional coating layer (241) diffuses at least partly into the first coating layer (240) and the second element (302) comprised in the first coating layer (240) diffuses at least partly into the at least one additional coating layer (241), forming a compound gradient. In one embodiment, the third element diffuses partly into the first coating layer (240), for example into at most 5, 10, 20, 30, 40, 50, 60, 70, 80, 90 or 99% of the thickness of the first coating layer (240). In one embodiment, the third element diffuses fully into the first coating layer (240) and reaches the base material (300). The third element may diffuse fully through the first coating layer (240) and into the base material (300). The concept of partially or fully diffusing is in this case to be understood in the same way as described above.

In one embodiment of the method, after step c) of heat treating is performed, at least one application of at least one further coating layer (242) comprising a fourth element (304) onto the already coated layer(s) (240, 241) is performed by a method selected from PVD and electroplating, each application optionally being followed by an additional step c) of heat treating. This leads to partial or full diffusion of the fourth element (304) into the layer beneath and diffusion of elements from the layer beneath into the further coating layer (242).

This way, a multilayer structure of compounds can be formed, providing specialized coatings with desired functional features.

In one embodiment of the method, the method selected is PVD. In one embodiment, the method selected for applying all coating layers is PVD. In another embodiment, the method selected for applying all coating layers is electroplating. In yet another embodiment, the both PVD and electroplating is performed.

In one embodiment of the method, the step c) of heat treating is performed at a temperature of between 600° C. and 1200° C., such as between 800° C. and 1200° C., between 900° C. and 1200° C., between 100° C. and 1200° C., between 600° C. and 1000° C., between 600° C. and 800° C., or between 700° C. and 900° C. In one embodiment, the duration of this heat treatment is 40-360 minutes, such as 50-80 minutes, 70-100 minutes, 90-160 minutes, 120-200 minutes, 180-250 minutes, 200-300 minutes or 250-360 minutes.

The temperature and time ranges varies greatly depending on the metal to be diffused. For example, Al can start to be partially diffused around 750° C. and a relatively low time duration is required. Additionally, the time depends on the thickness of the coated layer and desired level of diffusion.

Examples of parameters (temperature and time) that can be used for diffusion of elements into compounds:
Al layer into FeₓAl_{y} (on steel base): 700° C. for 2 h or 650° C. for 3 h
Al layer into Fe_{z}Al_{w} (on steel base): as above, with an additional increase of temperature up to 1050° C. for an additional 0.5 h
Al coating into AlₓCr_{y} and/or NiₓAl_{y} (on Ni:Cr:Fe alloy base): 1100° C. for 2 h
Al and an additional source of Fe to the base material into FeₓAl_{y} (on steel base): 825° C. for 3.5 h
Cr layer into CrC (on steel base):
   thin coating (3-5 μm): 885° C. for 3.5 h,
   medium coating (6-7 μm): 925° C. 4 h,
   thick coating (8-10 μm): 965° C. 4 h
Cr and Ti layers into Crₓ:Ti_{y}:C_{z} and/or CrC, TiC (on steel base): 1000° C. for 4 h.
Cr and B layers into Crₓ:By and/or Crₓ:Fe_{y}:C_{z}, CrC (on steel base): 975° C. for 3.5 h.
Cr and Al layers into Alₓ:Cr_{y} and/or Cr_{y}:Fe_{y}:C_{z}, CrC, FeₓAl_{y} (on a steel base): 975° C. for 3.5 h
Cr, Ti and Fe layers into Crₓ:Ti_{y}:C_{z} and/or CrC, Tic (all three elements in a mixture coated onto a steel base): 1050° C. for 4 h
Nb into NbC (on steel base): 1000° C. for around 10-18 h
V into VC (on steel base): 1000° C. for around 10-18 h

In one embodiment of the method, the base material (300) is an iron based alloy and the first element (301) is carbon. In one embodiment the base material (300) is a NiCr superalloy (e.g. Inconel). Other base materials can also be used for achieving desired compounds.

In one embodiment, the base material (300) is an iron based alloy that comprises a layer comprising silicon, wherein the second element (302) applied in the first coating layer (240) is aluminum and, wherein the compounds (310) formed by a reaction of the first element (301) in the base material (300) and the second element (302) applied in the first coating layer (240) are AlₓSi_{y} and FeₓAl_{y} intermetallic/metallic compounds. In one embodiment, first coating layer (240) is pure aluminum and the second element (302) is thereby aluminum, the base is a steel (comprising iron) and a an upper layer of FeₓAl_{y} and an intermediate layer of Fe_{z}Al_{w} is created (FIG. 4).

In one embodiment of the method, at least one of the second element (302), the third element (303) and the fourth element (304) is at least one chosen from the group consisting of carbon, iron, chromium, silicon, boron, aluminum, titanium, vanadium and niobium. More than one of these elements can be comprised in one layer. The composition of elements in each coated layer can be adapted to provide a combination giving the desired compounds of the final layers of the coating. In one embodiment, Chromium and Titanium are elements present in the applied coating layers. In one embodiment, Chromium and Boron are elements present in the applied coating layers. In one embodiment, Chromium and Aluminum are elements present in the applied coating layers. In one embodiment, Aluminum and Silicon are elements present in the applied coating layers.

In one embodiment of the method, the second element (302) comprised in the first coating layer (240) is chromium and the compound (310) formed is chromium carbide.

In one embodiment of the method, at least one of the following is performed:
carburization is performed before the step b) of applying the first coating layer (240)
at least one step c) of heat treating is performed in a carburizing atmosphere
at least one coating layer (240, 241, 242) is applied which comprises carbon.

This is done in order to avoid softening of the base material (300) which may occur due to depletion of carbon content in the base material (300) during the diffusion process. Carburization is a surface pre-treatment where the surface of the base material is enriched by a carbon-based gas.

In one embodiment of the method, at least one step c) of heat treating is performed in a controlled atmosphere comprising at least one selected from the group consisting of carbon, nitrogen and argon. This avoids oxidation of the outermost layer. Some metals are more likely to oxidise at higher temperature, instead of forming the carbide.

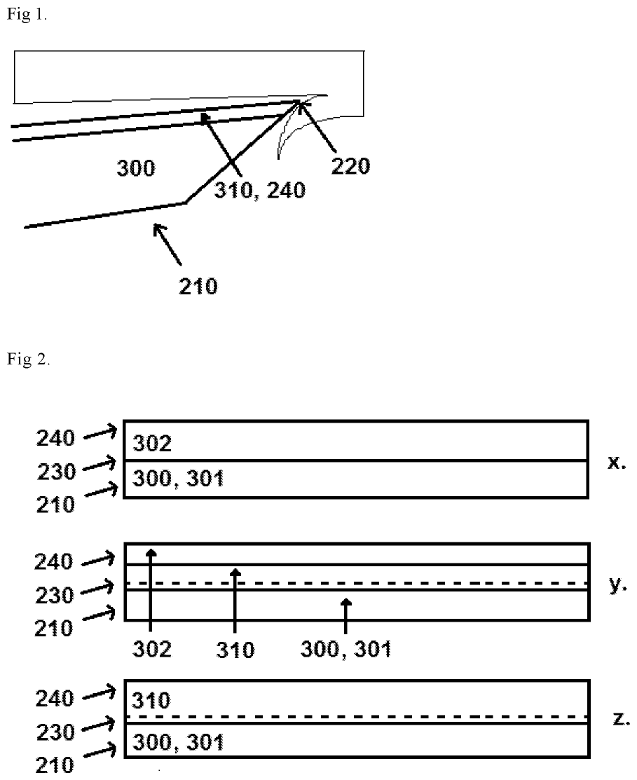

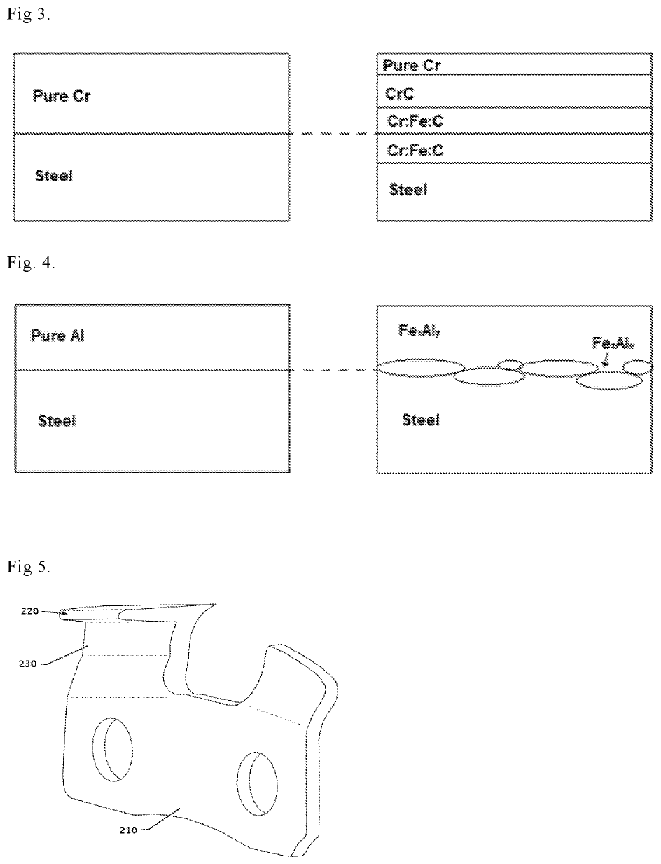

In one embodiment of the method, at least one of the first coating layer (240), the at least one additional coating layer (241) and the at least one further coating layer (242) is applied only to selected areas of the base, said selected areas contacting at least a part of the cutting edge (220) (FIG. 1).

In one embodiment of the method, each of the coating layers (240, 241, 242) applied has a thickness of 1-100 μm, preferably of 1-15 μm.

Thicknesses higher than 20 μm for PVD coatings may be unpractical because of the higher process time or need of much heating of the base material. For electroplating the range can be further increased, although a very high thickness will result in difficulties of diffusion and creating a gradient.

In a second aspect of the invention, a cutting device is provided, which is manufactured according to any of the embodiments of the described method.

The cutting device may be a device selected from the group consisting of a cutterlink for a chainsaw chain (FIG. 5), a cutting blade for a saw, a blade for a clearing saw, or a cutting equipment for a lawn mower. A cutting equipment for a lawn mower may include a blade or other cutting equipment for a walk-behind lawn mower, riding lawn mower (e.g., tractor, zero-turn mower, rider), or robotic mower.

1. A method for manufacturing a cutting device comprising the steps of:
a. providing a base comprising a cutting edge, wherein the base is made of a base material comprising a first element,
b. applying a first coating layer comprising a second element on the top surface of the base by a method selected from physical vapor deposition and electroplating,
c. heat treating the base,
wherein the step c) of heat treating is performed at a temperature and for a time period sufficient for the second element to diffuse partly into the base and for the first element to diffuse at least partly into the first coating layer,
whereby a gradient of a compound is formed by a reaction of the first element and the second element.

2. The method according to claim 1, wherein the heat treatment in step c) is carried out so that the diffusion of the first element occurs only partially into the first coating layer.

3. The method according to claim 1, wherein the heat treatment in step c) is carried out so that the diffusion of the first element occurs only into at most 5, 10, 20, 30, 40, 50, 60, 70, 80, 90 or 99% of the thickness of the first coating layer, in the direction from the base outwards through the first coating layer, in at least 90% of the area of the first coating layer.

4. The method according to claim 1, wherein the heat treatment in step c) is carried out so that the diffusion of the first element in the base material occurs fully into the first coating layer.

5. The method according to claim 1, wherein in step b) at least one additional coating layer comprising a third element is applied onto the first coating layer by a method selected from PVD and electroplating before step c) of heat treating, such that during the step c) of heat treating the third element comprised in the at least one additional coating layer diffuses at least partly into the first coating layer and the second element comprised in the first coating layer diffuses at least partly into the at least one additional coating layer.

6. The method according to claim 5, wherein after step c) is performed, at least one application of at least one further coating layer comprising a fourth element onto the already coated layer(s) is performed by a method selected from PVD and electroplating, each application optionally being followed by an additional step c) of heat treating.

7. The method according to claim 1, wherein the method selected is PVD.

8. The method according to claim 1, wherein the step c) of heat treating is performed at a temperature of between 600° C. and 1200° C., for a duration of 40-360 minutes.

9. The method according to claim 1, wherein the base material is an iron based alloy and the first element-is carbon.

10. The method according to claim 6, wherein at least one of the second element, the third element and the fourth element is at least one chosen from the group consisting of carbon, iron, chromium, silicon, boron, aluminum, titanium, vanadium and niobium.

11. The method according to claim 1, wherein the second element comprised in the first coating layer is chromium and the compound formed is chromium carbide.

12. The method according to claim 1, wherein at least one of the following is performed:
carburization is performed before the step b) of applying the first coating layer
at least one step c) of heat treating is performed in a carburizing atmosphere
at least one coating layer (240, 241, 242) is applied which comprises carbon.

13. The method according to claim 1, wherein at least one step c) of heat treating is performed in a controlled atmosphere comprising at least one selected from the group consisting of carbon, nitrogen and argon.

14. The method according to claim 1, wherein at least one of the first coating layer, the at least one additional coating layer and the at least one further coating layer is applied only to selected areas of the top surface, said selected areas contacting at least a part of the cutting edge.

15. The method according to claim 6, wherein each of the coating layers applied has a thickness of 1-100 μm.

16. A cutting device manufactured according to the method of claim 1.

17. The cutting device according to claim 16, wherein said cutting device is a device selected from the group consisting of a cutterlink for a chainsaw chain, a cutting blade for a saw, a blade for a clearing saw, and a cutting equipment for a lawn mower.
